(19) United States
(12) Patent Application Publication
(10) Pub. No.: US 2026/0056475 A1
(43) Pub. Date: Feb. 26, 2026

(54) RETICLE STITCHING FOR SEMICONDUCTORS

(71) Applicant: INTERNATIONAL BUSINESS MACHINES CORPORATION, Armonk, NY (US)

(72) Inventors: James Patrick Mazza, Saratoga Springs, NY (US); Reinaldo Vega, Mahopac, NY (US); Nicholas Anthony Lanzillo, Wynantskill, NY (US); David Wolpert, Poughkeepsie, NY (US); Takashi Ando, Eastchester, NY (US)

(21) Appl. No.: 18/815,001

(22) Filed: Aug. 26, 2024

(51) Int. Cl. G03F 7/00

(52) U.S. Cl. CPC G03F 7/70475; G03F 7/70633

(57) ABSTRACT

A semiconductor device includes a first field and a second field connected to the first field across a stitch region by a metal line. A merged portion within the stitch region connects portions of the metal line between the first field and the second field. The portions of the metal line each include angled portions that extend beyond a width of the metal line.

### BACKGROUND

The present invention generally relates to reticle stitching, and more particularly to systems, devices and methods that employ stich shapes that increase overlay margin between adjacent connected features.

Die sizes for photolithography are limited by a size of a standard lithographic reticle that results in one patterned field on a wafer. To save computational resources, dies that include multiple lithographic fields on a wafer have been considered. Features of a die are fabricated using a single lithographic field that corresponds to a single lithographic exposure using a single reticle. Multiple (e.g., two or more) adjacent lithographic fields can be employed with such fields being exposed using different reticles or the same reticle. When multiple adjacent lithographic fields are employed there is a need to interconnect features of these fields. For example, metal lines that extend between adjacent fields are needed for interconnection, routing, etc. The interconnection of such features is achieved through reticle stitching (or exposure stitching), where features from adjacent fields/reticles are adjoined or stitched together to provide, after exposure and other fabrication processing, features that extend across the boundary between adjacent fields on the wafer.

### SUMMARY

In accordance with an embodiment of the present invention, a semiconductor device includes a first field and a second field connected to the first field across a stitch region by a metal line. A merged portion within the stitch region connects portions of the metal line between the first field and the second field. The portions of the metal line each include angled portions that extend beyond a width of the metal line.

In accordance with another embodiment of the present invention, a semiconductor device includes a first field and a second field connected to the first field across a stitch region by a metal line. A merged portion within the stitch region connects portions of the metal line between the first field and the second field. The portions of the metal line each include crossed lines that extend beyond a width of the metal line.

In accordance with another embodiment of the present invention, a method for fabricating a semiconductor device includes transferring a first pattern to a photoresist through a first reticle, the first pattern having end lines having first angled end portions which extend beyond a width of the end lines; transferring a second pattern to the photoresist through a second reticle in a position adjacent to the first pattern to form a second pattern having end lines having second angled end portions which extend beyond a width of the end lines, such that the first angled portions and the second angled portions are merged in an overlap region between the first pattern and the second pattern; etching a dielectric layer in accordance with the first pattern and the second pattern; and forming metal lines in accordance with the first pattern and the second pattern which are connected through the first angled portions and the second angled portions.

These and other features and advantages will become apparent from the following detailed description of illustrative embodiments thereof, which is to be read in connection with the accompanying drawings.

### BRIEF DESCRIPTION OF THE DRAWINGS

The following description will provide details of preferred embodiments with reference to the following figures wherein:

FIG. 1 is a schematic view showing a reticle employed for transferring a pattern to a semiconductor device or wafer, in accordance with an embodiment of the present invention;

FIG. 2 is a layout view showing two filed having a stitch region therebetween including metal lines with angled portions in a merged connection, in accordance with an embodiment of the present invention;

FIG. 3 is a layout view showing merged patterns transferred to a semiconductor device by overlapping patterns from adjacent reticles, the merged patterns including angled portions, in accordance with an embodiment of the present invention;

FIG. 4 is a layout view showing merged patterns transferred to a semiconductor device by overlapping patterns from adjacent reticles and showing increased overlay margin as a result of the angled portions, in accordance with an embodiment of the present invention;

FIG. 5 is a layout view showing merged patterns formed into metal lines on a semiconductor device by merging metal lines with angled portions, in accordance with an embodiment of the present invention;

FIG. 6 is a layout view showing merged patterns transferred to a semiconductor device by overlapping patterns from adjacent reticles and showing increased overlay margin as a result of a crossed feature, in accordance with an embodiment of the present invention;

FIG. 7 is a layout view showing merged patterns formed into metal lines on a semiconductor device by merging metal lines with crossed features, in accordance with an embodiment of the present invention; and

FIG. 8 is a block/flow diagram showing a method for fabricating a semiconductor device by overlapping patterns in a stich region with angled/cross feature portions, in accordance with an embodiment of the present invention.

### DETAILED DESCRIPTION

In accordance with embodiments of the present invention, reticle stitching methods and devices so made are provided that increase overlay tolerance between features being stitched together. In an embodiment, metal lines in a device can be exposed and processed using an exposure pattern that includes angled portions. During lithographic processing, reticles are employed with associated patterns that need to be aligned to provide proper stitching (e.g., connections between features in different adjacent reticles).

In a standard process, metal lines are overlapped between reticles to ensure a continuous metal line without a short circuit or gap between adjacent portions. However, the overlay margin is limited and is further decreased by the ever-decreasing thickness of metal lines with new technologies. Reticle stitching faces difficulties due to known lithographic limitations inclusive of placement error (registration error), distortion, and other errors. These patterning problems can cause thin, high resistance metal lines or even disconnects.

In accordance with the present embodiments, pattern features and eventually metal lines include an angled portion in a stitching region. The angled portion permits a large overlay tolerance for resulting metal lines since an off-center metal line can still connect to the angle portion even if misaligned. The overlay tolerance increase can become more important as the need to provide larger dies having more complicated features using reticle stitching is necessary to support more dense and smaller feature sizes.

In another embodiment, the angle portion can be provided on opposing sides of a line in a crossed configuration, e.g., “X” configuration, “T” configuration, “+” sign configuration, or other crossed feature. The crossed configuration can provide an even greater overlay tolerance as the tolerance is increased in two dimensions.

In an embodiment, a reticle stitch includes a first region or stitch region, and second regions on opposing sides of the first region. The second regions are where portions of a feature enter the stitch region. The first region is where two reticles overlap in a photolithographic process. The photolithographic process can include an exposure process where a footprint of a metal line or feature is generated within a photoresist material. The reticles are employed in outlining a trench for the metal line or other feature to be formed.

In an example, the trench is outlined having a straight portion in each of the send regions and angled portions associated with each straight portion. The angled portions form a “V”shape.

The angled portions permit an increase in overlay tolerance to handle lateral misalignment between the second regions of the feature. In this way, when ethe feature become a metal line, the metal line, portions of the metal line are properly connected or stitched. The angled portions can include a same thickness as the thickness of the second regions. In other embodiments, the angle portions can have a different thickness from each other and from the second regions. The angled portions extend beyond the thickness of the straight portions of the second regions. The angled portions protrude outwardly from a sideline of the trench and provide an added feature when formed as a metal line. The angle can include, e.g., an angle of between 0 degrees and 180 degrees.

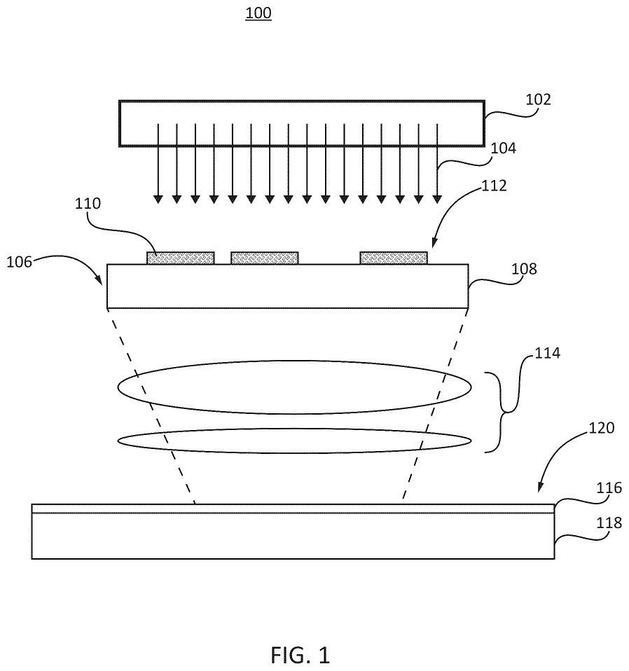

Referring now to the drawings in which like-numerals represent the same or similar elements and initially to FIG. 1, a schematic diagram shows lithographic patterning for overlapping line end features in accordance with an illustrative embodiment. A light source 102 provides exposure radiation 104 through a reticle 106. The reticle 106 includes a transparent substrate 108 and a light mask 110. The light mask 110 provided a pattern 112 in on and through the transparent substrate 108. Exposure radiation 104 continues from reticle 106 through optics 114 to expose a photoresist layer 116 on or over a substrate 118 (or wafer) forming a semiconductor device 120. Photoacids are generated that break down the resist polymer of photoresist layer 116, rendering it soluble in a developer solution. The pattern 112 is transferred from reticle 106 to the photoresist layer 116. Although a positive resist is shown, the present embodiments are applicable to negative resists and other forms of photolithographic processing.

Reticle stitching includes overlapping exposures or a same or different reticule. Regions between reticles or exposures can include line end features that span between the exposure fields. The exposure fields correspond to areas or regions patterned using separate lithography exposures. The fields may also be characterized as regions or tiles. The fields are patterned in separate lithography exposures that may include reticle stitched features or lines between these fields (e.g., metals line features or signal lines) that are to be connected across the fields. A reticle stitched feature crosses between reticles and exposure fields such that one portion or region is from a first reticle and exposure field and a second portion or regions from a second reticle and exposure field. Exposure fields can include a whole semiconductor die or chip, include portions of a die or semiconductor chip or include any other sized field.

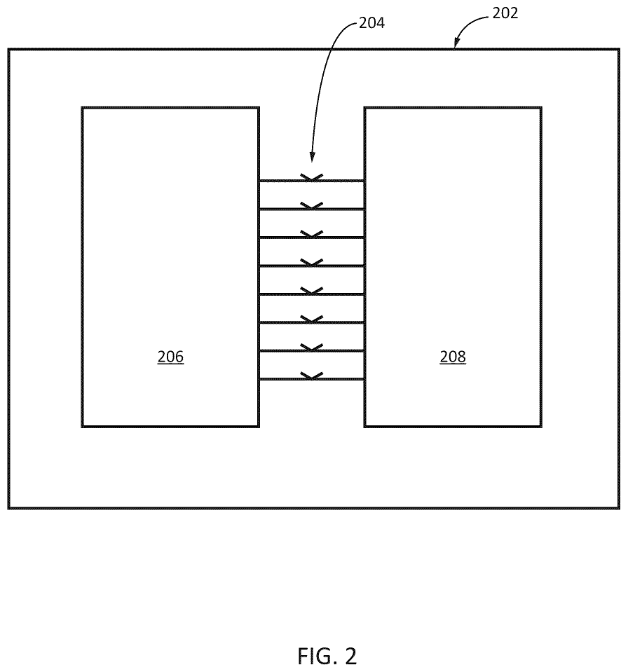

Referring to FIG. 2, in an example, a die 202 or dies can include reticle stitching features 204 connecting features between reticles in regions or fields 206, 208. The stitching features 204 can include line features fabricated by reticle stitching using overlapping line end features. The die 202 may be cut from a substrate or wafer. The fields 206, 208 correspond to areas or regions patterned using separate lithography exposures or separate reticle exposures. The fields 206, 208 are patterned in separate lithography exposures that may include reticle stitched features 204 or lines (e.g., metal line features or signal lines) that connect between the fields 206, 208. The reticle stitched features 204 can include a feature or line that spans between reticles and exposure fields 206, 208 where a first reticle is employed for exposure field 206 and a second reticle is employed for exposure field 208.

It should be understood that while only two exposure fields 206, 208, which correspond to reticle processing, are depicted, any number of exposure fields can be present including horizontally disposed fields and vertically disposed fields each having reticle stitching features 204 therebetween. The fields 206, 208 can include whole chips/dies, portions of chips/dies or groups of chips/dies.

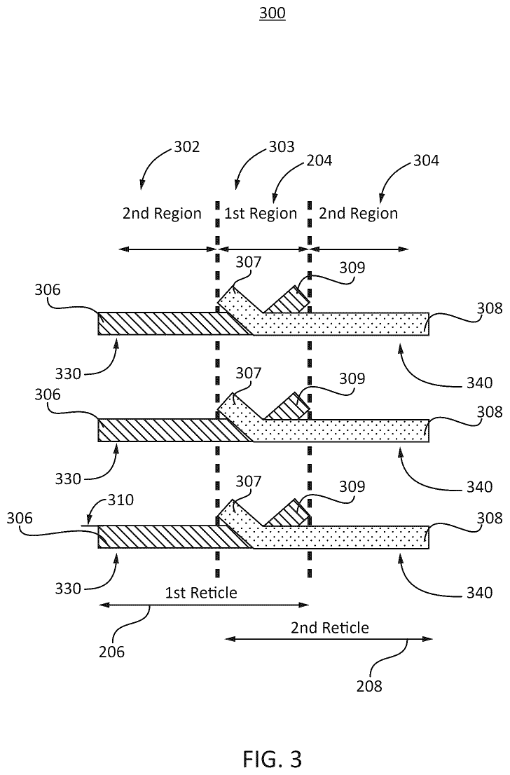

Referring to FIG. 3, a reticle stitching region 300 includes the reticle stitching features 204 between continuous portion regions 302 and 304. One or more lines 330 from one field 206 (or reticle) overlap one or more lines 340 from a second field 208 (or reticle) in an overlap region 303. The overlap region 303 includes the reticle stitching features 204. The reticle stitching features 204 include an angled portion 309 from lines 330 and an angled portion 307 from lines 340. The angled portions 307, 309 overlap to form a composite shape that will be processed to form a metal line of other feature.

The lines 330 and line 340 are meant to have portions 306 and 308 aligned to one another. Because different reticles or exposures are employed, these portions 306, 308 of lines 330, 340, respectively can be misaligned. Rather than having a complete misalignment, which would result in a short circuit or discontinuity between the lines 330, 340, the angled portions 307, 309 permit a larger overlay error to prevent misalignments from resulting in a short circuit when metal lines are eventually formed.

FIG. 3 shows a combined exposure region during a lithographic patterning of a photoresist. During further processing the composite shape of lines 330 and lines 340 will be employed to from trenches. The trenches will be filled and will eventually form metal lines having the angled portions 307 and 309. The angled portions 307 and 309 protrude from a side wall 310 of the composite shape.

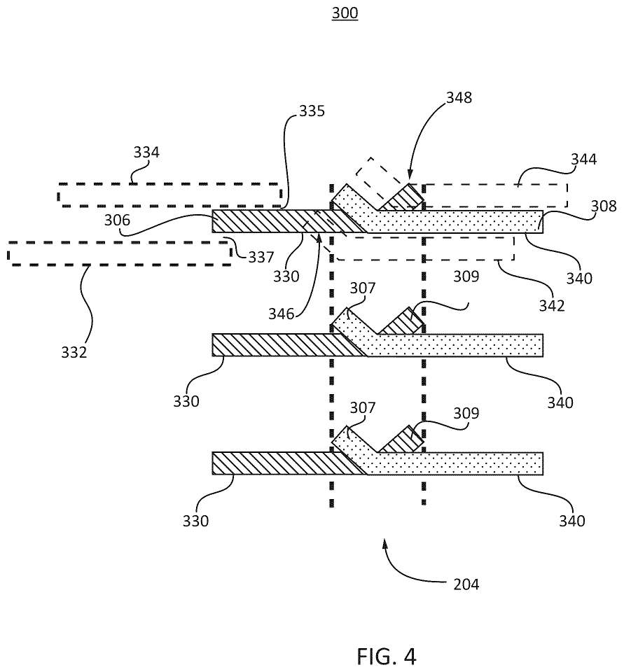

Referring to FIG. 4, portions 306 and 308 of lines 330 and 340 are to be aligned when formed as metal lines. Since each exposure in lithography has a certain placement error and/or distortion error, a combined placement error and/or distortion error of the two exposures can result in a gap 335, 337 in the overlapping exposure regions. Without the angled portions 307 and 309, misalignment of the straight lines during patterning could result in a short for later formed metal lines. For example, phantom lines show positions 332 and 334 where misalignment could result in a short circuit. If a position of line 330 is neutral or the center of an overlay tolerance zone, then a line placed in position 334 or position 332 would prevent a connection when metal lines were eventually formed. This is because the misalignment could be large enough to form a gap 335 or gap 337 between adjacent lines.

However, in accordance with embodiments or the present invention, the angled portions 307 and 309 permit a larger overlay tolerance so that misalignments can be accommodated. If a position of line 340 is neutral or the center of an overlay tolerance zone, then a line placed in position 342 or position 344 remains connected to line 330 at either point 346 or at point 348 due to the angled portions 307 and 309. When metal lines are eventually formed, it is much less likely that a short would or could result. Expanding overlay tolerances results in less time for lithographic processing, fewer costs and a reduction in failures due to misalignments.

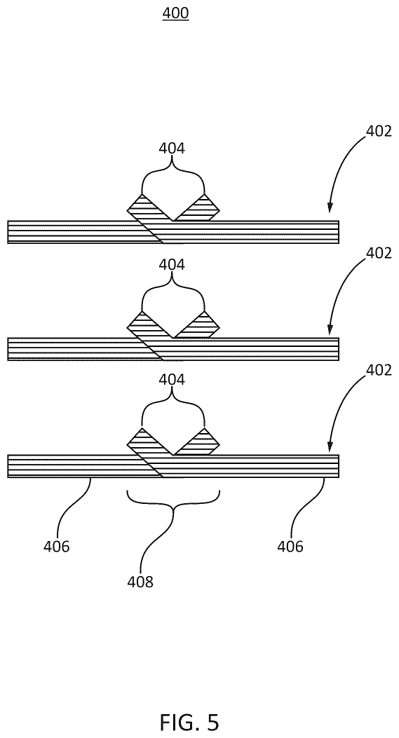

Referring to FIG. 5, after lithographic patterning of composite shapes in a reticle stitching in accordance with embodiments of the present invention, a mask is formed in the photoresist. The mask is transferred into a dielectric material of a dielectric layer forming trenches, which are etched into the dielectric material with the composite shape. The etching can include a reactive ion etch (RIE) or other suitable etching process. The trenches are filled with a conductive material, such as, e.g., Cu, W, Co, etc. and planarized, by e.g., a chemical mechanical polish (CMP), to form metal lines 402. A semiconductor device 400 includes metal lines 402 which connect across fields of the semiconductor device 400. The metal lines 402 include angled protrusions 404 integrally formed therein. The angled protrusions 404 extend beyond a thickness of the metal lines 402 forming a discontinuous shape at an edge of the metal line 402.

Continuous portions 406 of the metal lines 402 extend into adjacent fields (e.g., exposure fields). The composite shaped metal lines 402 connect the components formed in the adjacent fields. The composite shaped metal lines 402 include a merged portion 408 or region for each metal line 402 is defined by, e.g., both exposure of field 206 and 208 in FIG. 2, but not by either of the exposures independently. Merged portions 408 indicate a resultant stitch region of the overlay of patterns of two regions or fields associated with two reticles. The patterns used to provide merged portions 408 are provided in reticle patterns and transferred to a photoresist layer on or over a substrate or wafer (e.g., substrate 118 with photoresist layer 116 in FIG. 1. This overlapping of end line regions may be patterned using different reticles for each of fields 206, 208 or the same reticle for both of fields 206, 208. In examples where the same reticle is used, a same reticle is employed to pattern both fields 206, 208. In examples where different reticles are used, the same relationship of the features is provided using different reticles, but different reticles are employed.

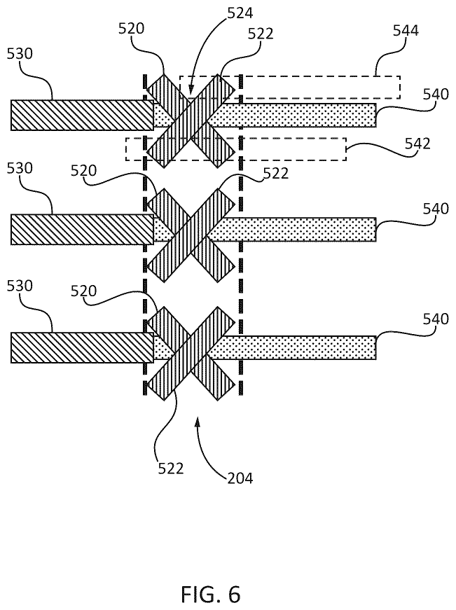

Referring to FIG. 6, lines 530 and 540 are to be aligned during a lithographic phase of processing so that misalignment when formed as metal lines does not result in a failure or discontinuous metal line. In accordance with another embodiment of the present invention, a crossed feature 524 include crossed lines 520 and 522. The lines 530 can be formed using a first reticle, and the lines 540 can be formed using a second reticle. The crossed feature 524 has one of the crossed lines 520 or 522 formed with the first reticle and the other formed with the second reticle. Alternately, the crossed feature can be formed by a third reticle, or the crossed feature can be formed entirely in the first reticle or entirely in the second reticle.

The crossed feature 524 includes an “X” shape that expands the overly tolerance in a parallel direction to lines 530, 540 and in a perpendicular direction to the lines 530 and 540. The crossed feature 524 can include other shapes, e.g., a “T” configuration, “+” sign configuration, or other crossed feature. The crossed feature 524 and angled portions 307, 309 can be used together in a same lithographic process. The crossed feature 524 can be employed on some of the lines while angle portions 307, 309 can be used on others. Phantoms position 542 and 544 show some of the misalignments that the cross feature 524 can accommodate. When metal lines are eventually formed, it is much less likely that a short would or could result. Expanding overlay tolerances results in less time for lithographic processing, fewer costs and a reduction in failures due to misalignments.

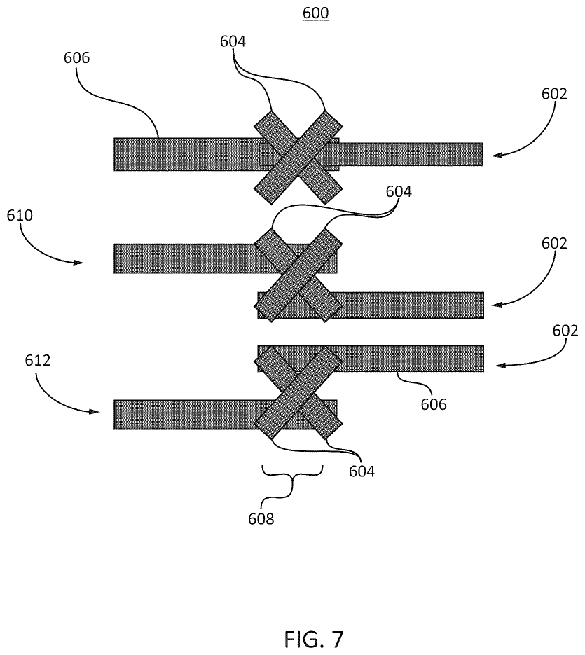

Referring to FIG. 7, after lithographic patterning of composite shapes in a reticle stitching in accordance with embodiments of the present invention, trenches are etched into a dielectric layer having the composite shape. The etching can include a RIE or other suitable etching process. The trenches are filled with a conductive material, such as, e.g., Cu, W, Co, etc. to form metal lines 602. A semiconductor device 600 includes metal lines 602 which connect across fields of the semiconductor device 600. The metal lines 602 include crosses 604 integrally formed therein. The crosses 604 extend beyond a thickness of the metal lines 602 forming a discontinuous shape at edges of the metal line 602.

Continuous portions 606 of the metal lines 602 extend into adjacent fields (e.g., exposure fields). The composite shaped metal lines 602 connect the components formed in the adjacent fields. The composite shaped metal lines 602 include a merged portion 608 or region for each metal line 602 defined by, e.g., both exposure of field 206 and 208 in FIG. 2, but not by either of the exposures independently. Merged portions 608 indicate a resultant stitch region of the overlay of patterns of two regions or fields associated with two reticles. The patterns used to provide merged portions 608 are provided in reticle patterns and transferred to a photoresist layer on or over a substrate or wafer (e.g., substrate 118 with photoresist layer 116 in FIG. 1). This overlapping of end line regions may be patterned using different reticles for each of fields 206, 208 or the same reticle for both of fields 206, 208. In examples where the same reticle is used, a same reticle is employed to pattern both fields 206, 208. In examples where different reticles are used, the same relationship of the features is provided using different reticles, but different reticles are employed. Misalignments 610 and 612 can be large and connections are still made through the crosses 604 between continuous portions 606.

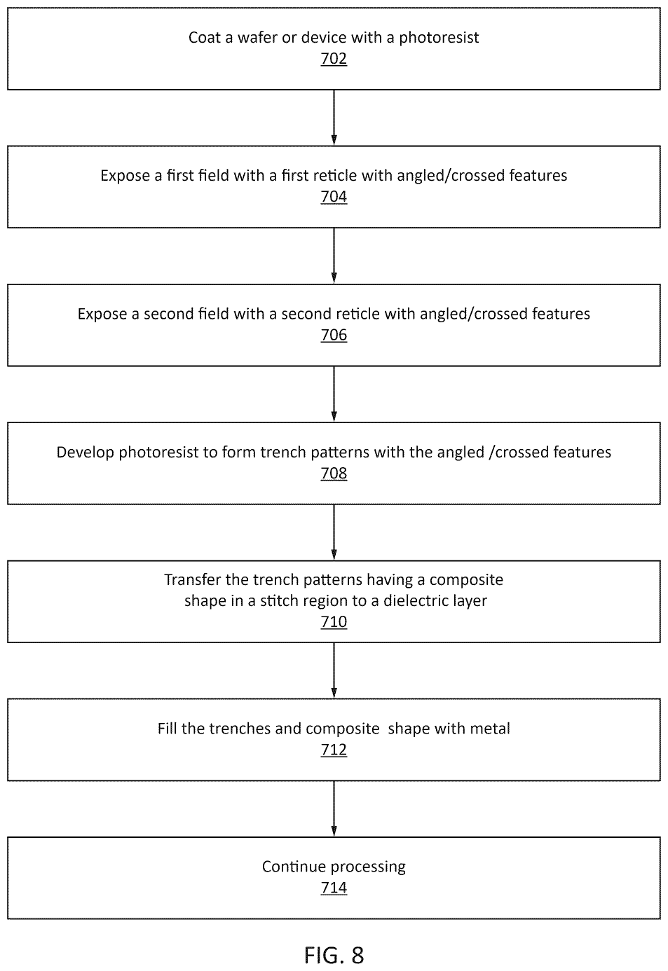

Referring to FIG. 8, methods for fabricating a semiconductor device are described in accordance with embodiments of the present invention. Reticle stitching includes a transition region or overlap regions between fields where the fields are each associated with a reticle for lithographic processing. The lithographic processing includes coating a wafer or substrate with a photoresist material in block 702.

The wafer or substrate can have a single layer or multiple layers. The wafer or substrate can include any suitable substrate structure, e.g., a bulk semiconductor, a semiconductor-on-insulator (SOI) substrate, etc., and preferably includes a monocrystalline semiconductor. In one example, the wafer or substrate can include a silicon-containing material. Illustrative examples of Si-containing materials can include, but are not limited to Si, SiGe, SiGeC, SiC and multi-layers thereof. Although silicon is the predominantly used semiconductor material in wafer fabrication, alternative semiconductor materials can be employed as additional layers, such as, but not limited to, germanium, gallium arsenide, gallium nitride, silicon germanium, cadmium telluride, zinc selenide, III-V materials or any other material or combinations thereof.

The wafer or substrate can include transistors, memory devices, capacitors, resistors or any other active or passive devices. The photoresist layer may include any suitable photoresist such as a positive photoresist material although negative photoresist can also be employed.

In block 704, a first field of the substrate is exposed using a first reticle. The first field is exposed to radiation to chemically alter the photoresist layer for a first metal line image. The exposure of photoresist regions generates photoacids that break down the resist polymer making it soluble in a developer solution. The first line image can include angled portions and/or crossed lines. In block 706, a second field of the substrate is exposed using a second reticle (e.g., the same or different than the first reticle). The second field is exposed to radiation to chemically alter the photoresist layer for a second metal line image. The second metal line image overlaps the first metal line image to form a reticle stitching region or an overlap region. The second line image can include angled portions and/or crossed lines. In an embodiment, a third reticle can be employed to form the crossed lines, if present.

In block 708, the exposed photoresist is developed to form trench patterns in the photoresist layer. The exposed photoresist may be developed using any suitable technique or techniques that remove the exposed portions of the photoresist and leave unexposed portions of the photoresist. In block 710, the photoresist layer pattern is transferred to an underlying dielectric layer by employing an etch process, e.g., RIE. The etch process results in trenches being formed in the dielectric layer in accordance with the composite shape including angled portions and/or crossed lines in the stitch region.

In block 712, the trenches are filled with a metal or metals to form a metal line or lines having the composite or merged shape. In block 714, processing continues to complete the semiconductor device.

It should be understood that a large number (N) reticles can be employed in lithographic processing. For example, a method can include patterning a first set of wires on a first reticle, patterning a second set of wires on a second reticle, patterning an (N-1)^{th} set of wires on an (N-1)^{th} reticle and patterning an N^{th} set of wires on an N^{th} reticle. Then transferring the pattern to a dielectric layer, and forming trenches by etching. Then, forming metal structures in accordance with embodiments of the present invention.

Reticle stitching between dies or within a die in accordance with embodiments of the present invention increases overlay, registration, and distortion margins for fabricating lines (e.g., metal lines) that span boundaries between reticles in die-to-die reticle stitching. Angle portions and crossed lines are forgiving of misregistration between adjacent stitched reticle fields. This results in less critical dimension (CD) variation and fewer failures.

Reference in the specification to “one embodiment” or “an embodiment” of the present invention, as well as other variations thereof, means that a particular feature, structure, characteristic, and so forth described in connection with the embodiment is included in at least one embodiment of the present invention. Thus, the appearances of the phrase “in one embodiment” or “in an embodiment”, as well any other variations, appearing in various places throughout the specification are not necessarily all referring to the same embodiment.

It is to be appreciated that the use of any of the following “/”, “and/or”, and “at least one of”, for example, in the cases of “A/B”, “A and/or B” and “at least one of A and B”, is intended to encompass the selection of the first listed option (A) only, or the selection of the second listed option (B) only, or the selection of both options (A and B). As a further example, in the cases of “A, B, and/or C” and “at least one of A, B, and C”, such phrasing is intended to encompass the selection of the first listed option (A) only, or the selection of the second listed option (B) only, or the selection of the third listed option (C) only, or the selection of the first and the second listed options (A and B) only, or the selection of the first and third listed options (A and C) only, or the selection of the second and third listed options (B and C) only, or the selection of all three options (A and B and C). This may be extended, as readily apparent by one of ordinary skill in this and related arts, for as many items listed.

The flowchart and block diagrams in the Figures illustrate the architecture, functionality, and operation of possible implementations of systems, methods, and computer program products according to various embodiments of the present invention. In this regard, each block in the flowchart or block diagrams may represent a module, segment, or portion of instructions, which comprises one or more executable instructions for implementing the specified logical function(s). In some alternative implementations, the functions noted in the blocks may occur out of the order noted in the Figures. For example, two blocks shown in succession may, in fact, be accomplished as one step, executed concurrently, substantially concurrently, in a partially or wholly temporally overlapping manner, or the blocks may sometimes be executed in the reverse order, depending upon the functionality involved. It will also be noted that each block of the block diagrams and/or flowchart illustration, and combinations of blocks in the block diagrams and/or flowchart illustration, can be implemented by special purpose hardware-based systems that perform the specified functions or acts or carry out combinations of special purpose hardware and computer instructions.

Having described preferred embodiments for reticle stitching (which are intended to be illustrative and not limiting), it is noted that modifications and variations can be made by persons skilled in the art in light of the above teachings. It is therefore to be understood that changes may be made in the particular embodiments disclosed which are within the scope of the invention as outlined by the appended claims. Having thus described aspects of the invention, with the details and particularity required by the patent laws, what is claimed and desired protected by Letters Patent is set forth in the appended claims.

1. A semiconductor device, comprising:
a first field;
a second field connected to the first field across a stitch region by a metal line; and
a merged portion within the stitch region, the merged portion connecting portions of the metal line between the first field and the second field, the portions of the metal line each including angled portions that extend beyond a width of the metal line.

2. The semiconductor device as recited in claim 1, wherein the angled portions of the portions of the metal line form a “V” shape.

3. The semiconductor device as recited in claim 1, wherein the merged portion connects the portions of the metal line at the angled portions.

4. The semiconductor device as recited in claim 1, wherein the portions of the metal line are laterally offset relative to each other.

5. The semiconductor device as recited in claim 1, wherein the first field includes conductive structures patterned with a first reticle, and the second field includes conductive structures patterned with a second reticle.

6. The semiconductor device as recited in claim 1, wherein the first field includes a semiconductor die.

7. The semiconductor device as recited in claim 1, wherein the first field and the second field include portions of a semiconductor die.

8. A semiconductor device, comprising:
a first field;
a second field connected to the first field across a stitch region by a metal line; and
a merged portion within the stitch region, the merged portion connecting portions of the metal line between the first field and the second field, the portions of the metal line each including crossed lines that extend beyond a width of the metal line.

9. The semiconductor device as recited in claim 8, wherein the crossed lines of the portions of the metal line form an “X” shape.

10. The semiconductor device as recited in claim 8, wherein the merged portion connects the portions of the metal line at the crossed lines.

11. The semiconductor device as recited in claim 8, wherein the portions of the metal line are laterally offset relative to each other.

12. The semiconductor device as recited in claim 8, wherein the first field includes conductive structures patterned with a first reticle, and the second field includes conductive structures patterned with a second reticle.

13. The semiconductor device as recited in claim 12, wherein the crossed lines are patterned with a third reticle.

14. The semiconductor device as recited in claim 8, wherein the first field includes a semiconductor die.

15. The semiconductor device as recited in claim 8, wherein the first field and the second field include portions of a semiconductor die.

16. A method for fabricating a semiconductor device, comprising:
transferring a first pattern to a photoresist through a first reticle, the first pattern having end lines having first angled end portions which extend beyond a width of the end lines;
transferring a second pattern to the photoresist through a second reticle in a position adjacent to the first pattern to form a second pattern having end lines having second angled end portions which extend beyond a width of the end lines, such that the first angled end portions and the second angled end portions are merged in an overlap region between the first pattern and the second pattern;
etching a dielectric layer in accordance with the first pattern and the second pattern; and
forming metal lines in accordance with the first pattern and the second pattern which are connected through the first angled end portions and the second angled end portions.

17. The method as recited in claim 16, wherein the first angled end portions and the second angled end portions form a ‘V” shape on a metal line.

18. The method as recited in claim 16, wherein the first angled end portions and the second angled end portions form an “X” shape on a metal line.

19. The method as recited in claim 16, wherein the “X” shape on the metal line is patterned with a third reticle.

20. The method as recited in claim 16, wherein the end lines of the first pattern are laterally offset relative to the end lines of the second pattern.
